(19) United States
(12) Patent Application Publication
(10) Pub. No.: US 2009/0001529 A1
(43) Pub. Date: Jan. 1, 2009

(54) PACKAGE STACKING USING UNBALANCED MOLDED TSOP

(76) Inventors: Ming Hsun Lee, Taichung (TW); Cheemen Yu, Madison, WI (US)

Correspondence Address: VIERRA MAGEN/SANDISK CORPORATION, 575 MARKET STREET, SUITE 2500, SAN FRANCISCO, CA, 94105, US

(21) Appl. No.: 11/769,149

(22) Filed: Jun. 27, 2007

(51) Int. Cl. H01L 23/02

(52) U.S. Cl. 257/666; 257/E23.18

(57) ABSTRACT

A semiconductor package assembly is disclosed including a pair of stacked leadframe-based semiconductor packages. The first package is encapsulated in a mold compound so that the electrical leads emanate from the sides of the package, near a bottom surface of the package. The first package may be stacked atop the second package by aligning the exposed leads of the first package with the exposed leads of the second package and affixing the respective leads of the two packages together. The vertical offset of leads toward a bottom of the first package provides a greater overlap with leads of the second package, thus allowing a secure bonding of the leads of the respective packages.

### CROSS-REFERENCE TO RELATED APPLICATION

The following application is cross-referenced and incorporated by reference herein in its entirety:

U.S. patent application Ser. No. ______ [Attorney Docket No. SAND-01255US0], entitled “Method Of Package Stacking Using Unbalanced Molded TSOP,” by Ming Hsun Lee, et al., filed on even date herewith.

### BACKGROUND OF THE INVENTION

1. Field of the Invention

Embodiments of the present invention relate to a method of fabricating a semiconductor package, and a semiconductor package formed thereby.

2. Description of the Related Art

As the size of electronic devices continue to decrease, the associated semiconductor packages that operate them are being designed with smaller form factors, lower power requirements and higher functionality. Currently, sub-micron features in semiconductor fabrication are placing higher demands on package technology including higher lead counts, reduced lead pitch, minimum footprint area and significant overall volume reduction.

One branch of semiconductor packaging involves the use of a leadframe, which is a thin layer of metal on which one or more semiconductor die are mounted. The leadframe includes electrical leads for communicating electrical signals from the one or more semiconductors to a printed circuit board or other external electrical devices. Common leadframe-based packages include plastic small outlined packages (PSOP), thin small outlined packages (TSOP), and shrink small outline packages (SSOP). Components in a conventional leadframe package are shown in FIGS. 1 and 2. The illustrated components may be used for example in a TSOP package, which comes standard in 32-lead, 40-lead, 48-lead and 56-lead packages (fewer leads are shown in the figures for clarity).

FIG. 1 shows a leadframe 20 before attachment of a semiconductor die 22. A typical leadframe 20 may include a number of leads 24 having first ends 26 for attaching to semiconductor die 22, and a second end 28 (FIGS. 3 and 4) for affixing to a printed circuit board or other electrical component. Leadframe 20 may further include a die attach pad 30 for structurally supporting semiconductor die 22 on leadframe 20. While die attach pad 30 may provide a path to ground, it conventionally does not carry signals to or from the semiconductor die 22. In certain leadframe configurations, it is known to omit die attach pad 30 and instead attach the semiconductor die directly to the leadframe leads in a so-called chip on lead (COL) configuration.

Semiconductor leads 24 may be mounted to die attach pad 30 as shown in FIG. 2 using a die attach compound. Semiconductor die 22 is conventionally formed with a plurality of die bond pads 34 on first and second opposed edges on the top side of the semiconductor die. Once the semiconductor die is mounted to the leadframe, a wire bond process is performed whereby bond pads 34 are electrically coupled to respective electrical leads 24 using a delicate wire 36. The assignment of a bond pad 34 to a particular electrical lead 24 is defined by industry standard specification. FIG. 2 shows less than all of the bond pads 34 being wired to leads 24 for clarity, but each bond pad may be wired to its respective electrical lead in conventional designs. It is also known to have less than all of the bond pads wired to an electrical lead as shown in FIG. 2. It is also known to mount more than one die on leadframe 20 in a stacked relationship.

FIG. 3 shows a cross-sectional side view of a pair of semiconductor packages 40a and 40b. Package 40a includes one or more semiconductor die 22a wire bonded to a leadframe 20a. Once wire bonding is completed, a molding process may be performed to encase the components in a molding compound 38a to form the finished package 40a. The same processes occur to form semiconductor package 40b. As shown for each package, it is known to recess or “down-set” the semiconductor die within the leadframe in order to balance the semiconductor die against the forces of the molding compound as it flows around the die and leadframe.

The leads 24 extend from the molded packages 40a and 40b, terminating in lead ends 28a and 28b, respectively. The leads 24 in the packages come in standard lengths. For example, in a 48 lead TSOP package, leads may extend 1.02 mm from the package. Referring first to package 40b, the leads 24b may include a generally “S”-shaped bend so as to have an end 28b generally parallel to and at the elevation of the bottom of the package. The ends 28b may be physically and electrically coupled to a host device such as a printed circuit board in an SMT (surface mount technology) soldering operation to allow the exchange of signals between the package 40b and the printed circuit board.

Instead of mounting to a printed circuit board (PCB), it is also known to bend the portion of the leads 24 substantially straight downward, as in leads 24a in package 40a. The ends 28a of the leads 24a of package 40a may then be aligned with and bonded to the leads 24b of package 40b as shown in prior art FIG. 4 to form a multi-package chip assembly 50. A problem exists in forming such multi-package chip assemblies 50 in that, given the standard lengths of the leads 24 in packages 40a and 40b, and giving the standard thicknesses of packages 40a and 40b, the leads 24a in package 40a barely reach the leads 24b in package 40b. In particular, leads 24a conventionally emanate from the package 40a a distance, x, of approximately 0.44 mm from a top of the package and a distance, y, of approximately 0.51 mm from a bottom of the package. Being about 1.02 mm in length, each lead 24a extends beyond the bottom of package 40a and overhangs package 40b by about 0.51 mm. The leads 24b similarly emanate from package 40b a distance, x, of about 0.44 mm from a top surface of the package 40b. This leaves an overlap between leads 24a and 24b of 0.51 mm-0.44 mm, or 0.07 mm.

Such a small overlap can lead to unreliable bonding of certain leads of the respective packages to each other, and a potential faulty operation of the multi-package assembly. Moreover, the small overlap makes it difficult to provide an adhesive between the respective semiconductor packages in the multi-package assembly, thus making it more likely that the respective packages may become dislodged from each other over time.

### SUMMARY OF THE INVENTION

The present invention, roughly described, relates to a method of fabricating a semiconductor package assembly including a pair of stacked semiconductor packages, and a semiconductor package assembly formed thereby. In embodiments, the package assembly may include a first package having a leadframe and one or more semiconductor die coupled to electrical leads of the leadframe. The first package is encapsulated in a mold compound so that the electrical leads emanate from the sides of the package, near a bottom surface of the package. In particular, the integrated circuit may be molded in a mold cavity so that the leads are positioned in the cavity near a bottom of the cavity. Thus, when mold compound is injected into the cavity, the resulting package includes electrical leads near a bottom surface of the package.

The first semiconductor package may be stacked atop a second semiconductor package. The second semiconductor package may be the same as or different from the first semiconductor package. In embodiments, the second semiconductor package may be a leadframe-based package, having leads which extend out of the mold compound in a manner similar to conventional semiconductor packages. That is, the leads from the second package may extend out of the sides of the mold compound approximately at the vertical center of the mold compound. The leads of the second package may be generally “S”-shaped, as in conventional leadframe-based packages, to allow the second package to be surface mounted to a host device such as a PCB.

The first package may be stacked atop the second package by aligning the exposed leads of the first package with the exposed leads of the second package and affixing the respective leads of the two packages together. The vertical offset of leads toward a bottom of the first package provides a greater overlap with leads of the second package, thus allowing a secure bonding of the leads of the respective packages. Moreover, the overlap of the leads is sufficient to allow the inclusion of an adhesive layer between the first and second packages. Thus, not only does the increased overlap of leads allow a more secure bond between respective leads, but the additional overlap allows a more secure mounting of the first and second packages together.

### BRIEF DESCRIPTION OF THE DRAWINGS

FIG. 1 is an exploded perspective view of a conventional leadframe and semiconductor die.

FIG. 2 is a perspective view of a conventional semiconductor die wire bonded to a conventional leadframe.

FIG. 3 is a cross-sectional side view of a pair of conventional semiconductor packages each including a semiconductor die and a leadframe encased in mold compound.

FIG. 4 is a cross-sectional side view of a conventional multi-package assembly formed from the semiconductor packages shown in FIG. 3.

FIG. 5 is a perspective view of a semiconductor die and leadframe for use in embodiments of the present invention.

FIG. 6 is a cross-sectional side view of a semiconductor package including a vertically offset leadframe encapsulated within mold compound.

FIG. 7 is a cross-sectional side view of a semiconductor package on which the vertically offset semiconductor package of FIG. 6 may be mounted.

FIG. 8 is a cross-sectional side view of a multi-package assembly according to an embodiment of the present invention.

FIG. 9 is a cross-sectional side view of a multi-package assembly according to an alternative embodiment of the present invention.

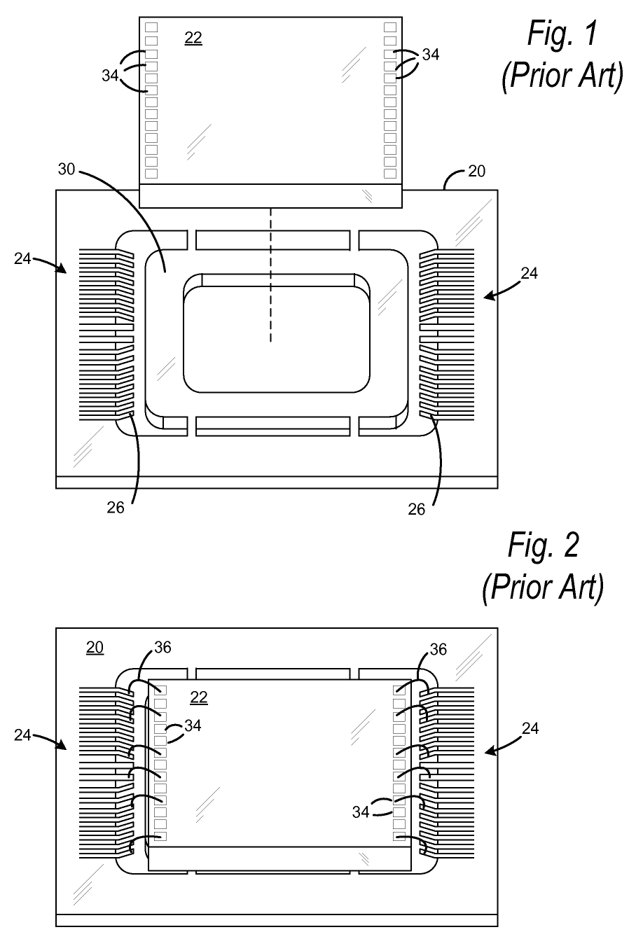

### DETAILED DESCRIPTION

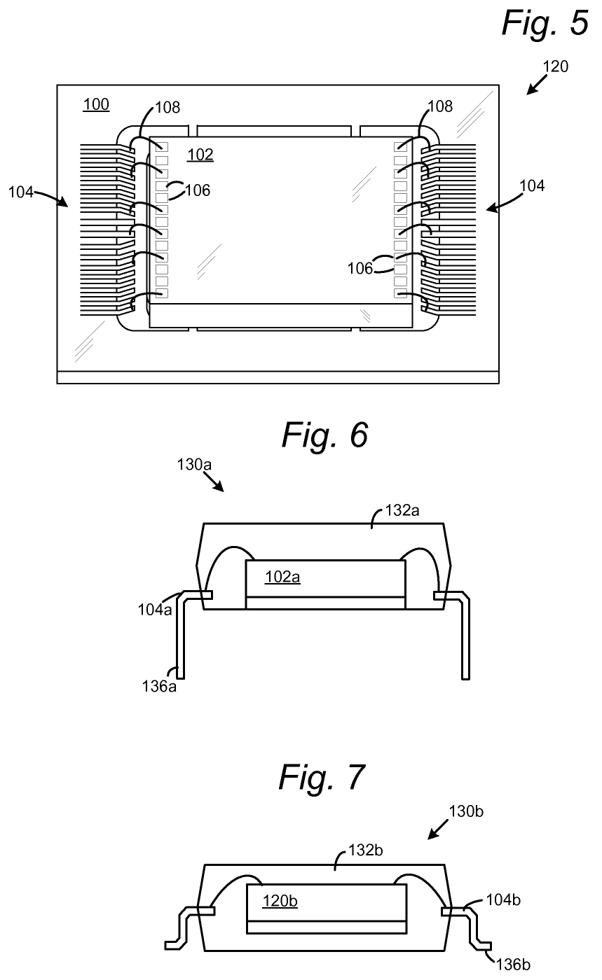

Embodiments of the present invention will now be described in reference to FIGS. 5-9 which in general relate to a method of fabricating a semiconductor package, and a semiconductor package formed thereby. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

FIG. 5 is a top perspective view of a leadframe and die assembly and FIGS. 6 and 7 show cross-sectional side views of a pair of semiconductor packages. The leadframe and die assembly described hereinafter may be used in the package shown in FIG. 6 and/or the package shown in FIG. 7. Referring again to FIG. 5, there is shown a leadframe 100, which may be batch processed from a panel of such leadframes to achieve economies of scale. Leadframe 100 may include a die paddle (not shown) for supporting one or more semiconductor die 102. Leadframe 100 further includes electrical leads 104 for communicating electrical signals to and from the one or more semiconductor die 102 and an external electronic device such as a PCB or other component to which the finished package is mounted. While shown on two opposed sides, it is understood that leads 104 may be on a single side, two adjacent sides, three sides or all four sides of leadframe 100.

Leadframe 100 may be formed of a planar or substantially planar piece of metal, such as copper or copper alloys, plated copper or plated copper alloys, Alloy 42 (42Fe/58Ni), or copper plated steel. Leadframe 100 may be formed of other metals and materials known for use in leadframes. In embodiments, leadframe 100 may also be plated with silver, gold, nickel palladium, or copper.

Leadframe 100 may be formed by known fabrication processes, such as for example, chemical etching. In chemical etching, a photoresist film may be applied to the leadframe. A pattern photomask containing the outline of the die paddle, leads 104 and other features of leadframe 100 may then be placed over the photoresist film. The photoresist film may then be exposed and developed to remove the photoresist from areas on the conductive layers that are to be etched. The exposed areas are next etched away using an etchant such as ferric chloride or the like to define the pattern in the leadframe 100. The photoresist may then be removed. Other known chemical etching processes are known. The leadframe 100 may alternatively be formed in a mechanical stamping process using progressive dies. As is known, mechanical stamping uses sets of dies to mechanically remove metal from a metal strip in successive steps.

After formation of the leadframe, one or more semiconductor die 102 may be mounted to the die paddle of leadframe 100. Although not critical to the present invention, the one or more semiconductor die 102 may include a flash memory chip (NOR/NAND) and a controller chip such as an ASIC. More than one memory die may be included in alternative embodiments, and the controller die may be omitted in alternative embodiments. Moreover, it is understood that the leadframe 100 may be used in a variety of semiconductor packages, and a variety of different semiconductor chips and components may be included within the semiconductor package formed from leadframe 100 and semiconductor die 102. When a plurality of die 102 are provided, an interposer layer (not shown) may be included for transferring signals between the upper die and the leadframe 100 as is known in the art. The interposer layer may be omitted in alternative embodiments.

The one or more semiconductor die 102 may be mounted to leadframe 100 in a known manner using a dielectric die attach compound, film or tape. The die 102 may include die bond pads 106 receiving bond wires 108 (some of which die bond pads and bond wires are labeled in FIG. 5). The bond wires are provided in a known wire bond process to electrically couple the semiconductor die 102 to the electrical leads 104. It is understood that more or less bond wires 108 may be included in alternative embodiments. The wire bonded semiconductor die 102 and leadframe 100 form an integrated circuit 120.

Referring now to the cross-sectional side view of FIG. 6, a first semiconductor package 130a may be formed using an integrated circuit 120a as described above with respect to circuit 120 of FIG. 5. Package 130a may be formed by encapsulating the integrated circuit 120a within mold compound 132a. Mold compound 132a may be an epoxy such as for example available from Sumitomo Corp. and Nitto Denko Corp., both having headquarters in Japan. Other mold compounds from other manufacturers are contemplated. The mold compound 132a may be applied according to various processes, including by transfer molding or injection molding techniques to form package 130a. Semiconductor package 130a includes a plurality of leads 104a emanating from mold compound 132a and terminating at ends 136a. In embodiments, leads 104a emanate from package 130a and extend approximately straight downward as shown in FIG. 6.

In order to encapsulate integrated circuit 120a, integrated circuit 120a is positioned within a mold including top and bottom mold plates defining a cavity around integrated circuit 120a. Leads 104a protrude outside of the cavity defined by the top and bottom mold plates. In accordance with embodiments of the present invention, the integrated circuit 120a, or at least leads 104a, may be vertically offset within the mold cavity to result in an encapsulated package 130a where leads 104a protrude out of the sides of mold compound 132a toward a bottom of the package as shown in FIG. 6.

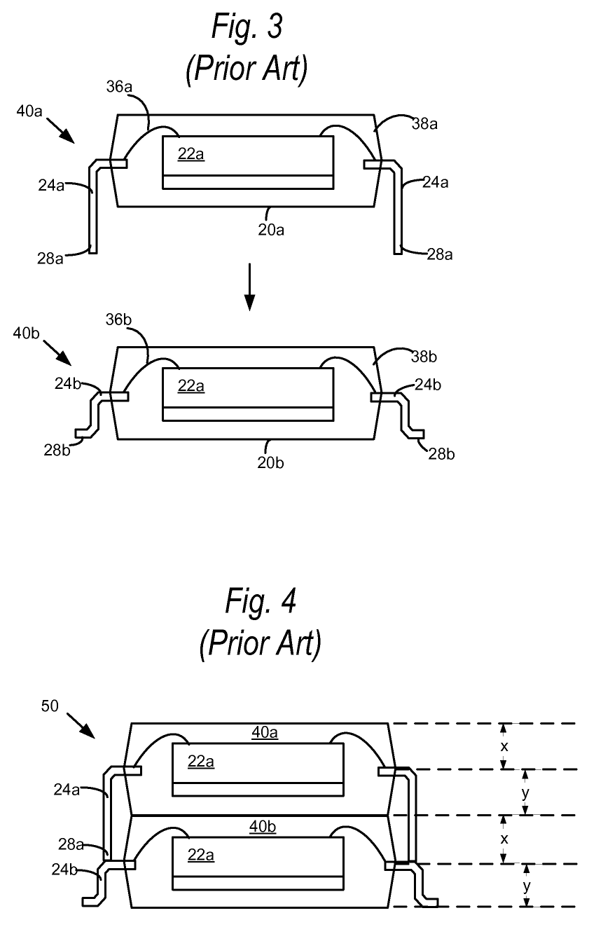

In conventional leadframe packages, the integrated circuit may be positioned within the mold cavity generally in the middle of the cavity along the vertical dimension. That is, there is generally the same amount of space above the integrated circuit as there is below the integrated circuit. Accordingly, when mold compound is injected into the chamber, the mold compound flows above and below the integrated circuit. Upon hardening, the leads of the integrated circuit emanate from the sides of the mold compound, roughly vertically centered with respect to the mold compound as shown in prior art FIGS. 3 and 4.

By contrast, in embodiments of the present invention, the integrated circuit 120a may be located in the mold cavity so that there is more space above the integrated circuit than below it. This may be accomplished by providing a top mold plate with a deeper cavity than the bottom mold plate. For example, in embodiments, the leads may emanate from a bottom one-third, or a bottom one-quarter of the mold cavity. In embodiments, the leads may emanate specifically 0.15 mm from a bottom surface of the mold cavity.

Thus, upon injection of the mold compound and hardening of the mold compound, leads 104a emanate from the sides of mold compound 132a near a bottom surface of semiconductor package 130a. Consequently, the ends 136a of standard-sized leads 104a extend further below a bottom surface of the mold compound 132a as compared to conventional leadframe-based semiconductor packages. As explained in greater detail below, this allows a greater overlap of leads 104a with leads of a second semiconductor package to which semiconductor package 130a is coupled. This provides a more secure and reliable bond between the leads of the respective packages.

As explained in the Background section, a semiconductor die may be down-set with respect to the surrounding electrical leads. In an alternative embodiment, the die paddle on which semiconductor die 102 is mounted may either reside in substantially the same plane as leads 104a adjacent to the semiconductor die, or may even be above the adjacent portions of leads 104a. This allows the die paddle and the semiconductor die of integrated circuit 120a to be located approximately at the vertical center of the mold chamber, while the leads 104a are positioned to extend out of the sides of mold compound 132a, near a bottom of mold compound 132a, as described above and with respect to FIG. 6.

FIG. 7 is a cross-sectional side view of a second semiconductor package 130b. As explained below, package 130a may be stacked atop package 130b to form a multi-package assembly. Package 130b may be the same as or different from package 130a. Package 130a may include an integrated circuit 120b, such as circuit 120 described above, which is encapsulated in mold compound 132b to form the package 130b. Semiconductor package 130b may include a plurality of leads 104b emanating from mold compound 132b and terminating at ends 136b. The leads 104b may be generally “S”-shaped, as in conventional leadframe-based packages, to allow package 130b to be surface mounted to a host device such as a PCB (not shown).

Semiconductor package 130b may be encapsulated in mold compound in a manner similar to conventional semiconductor packages. Mainly, leads 104b may extend out of the sides of mold compound 132b approximately at the vertical center of the mold compound 132b. However, in an alternative embodiment, it is understood that the leads 104b may be slightly vertically offset above a vertical center line of a mold compound 132b. This may be accomplished by providing a top mold plate with a shallower cavity than the bottom mold plate. Such an embodiment provides even greater overlap with leads 104a of semiconductor package 130a. Any such vertical offset of the leads 104b from the package 130b is slight, so that ends 136b still having sufficient space to be soldered to a PCB by surface mount technology.

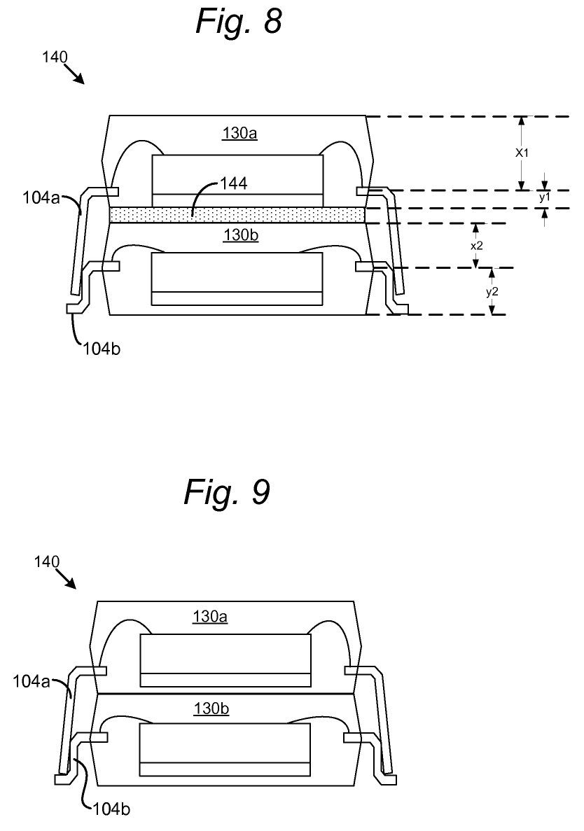

FIG. 8 is a cross-sectional side view of a multi-package assembly 140 formed according to embodiments of the present invention using packages 130a and 130b. As seen in FIG. 8, a vertical offset of leads 104a toward a bottom of package 130a provides a greater overlap with leads 104b of package 130b. This overlap may be sufficiently large to allow the inclusion of an adhesive layer 144 between packages 130a and 130b in embodiments of the present invention. Adhesive layer 144 may be any of a variety of known adhesives for securely affixing semiconductor package 130a to semiconductor package 130b. Thus, not only does the increased overlap of leads 104a allow a more secure bond between respective leads 104a and 104b, but the additional overlap also allows a more secure mounting of package 130a to package 130b. In embodiments, adhesive layer 144 may be less than or equal to 3 mils, or approximately 0.076 mm, though it may be thicker than that in alternative embodiments.

As indicated above, in embodiments, a semiconductor package may have a height of approximately 0.95 mm, where the leads protrude out of the sides of the package 0.44 mm from the top surface and 0.51 mm from the bottom surface. According to embodiments of the present invention, the leads 104a may be vertically offset downward a distance of 0.20 mm to 0.40 mm relative to this conventional design, and in further embodiments, the leads 104a may be vertically offset downward a distance of 0.36 mm. It is understood that the vertical offset of leads 104a may be less than 0.20 mm and greater than 0.40 mm in alternative embodiments of semiconductor package 130a.

Referring now to dimensions shown in FIG. 8, an offset of 0.36 mm downward of leads 104a can result in leads 104a being a distance, X1, of 0.8 mm from a top surface of semiconductor package 130a, and a distance, Y1, of 0.15 mm from the bottom surface of package 130a. Given the above dimensions, leads 104a may extend down below the bottom surface of semiconductor package 130a a distance of approximately 0.87 mm. Given a thickness of adhesive layer 144 of approximately 0.076 mm, and a position of leads 104b 0.44 mm below a top surface of semiconductor package 130b, this results in an overlap between leads 104a and 104b of:

0.87 mm-0.44 mm-0.076 mm, or 0.354 mm.

With this overlap, respective leads 104a may be securely affixed to corresponding leads 104b. It is understood that each of the above dimensions is by way of example and may vary in alternative embodiments.

The leads 104a may be affixed to the leads 104b by a variety of methods including for example ultrasonic welding. It is understood that less than all of leads 104a may be affixed to leads 104b.

Referring now to FIG. 9, it is understood that the multi-package assembly 140 may be formed without adhesive layer 144. In such embodiments, the overlap between leads 104a and 104b may be even greater, thus allowing a secure bond between respective leads of packages 130a and 130b sufficient to maintain the packages together.

The above-described semiconductor die and leadframe may be used to form a TSOP 48-pin multi-package configuration. It is understood however that the number of pins and the type of leadframe package may vary significantly in alternative embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A portable memory package, comprising:
a first semiconductor package, including:
a leadframe including electrical leads,
one or more semiconductor die bonded and electrically coupled to the leadframe, and
mold compound for encapsulating the leadframe and one or more semiconductor die, the electrical leads emanating from sides of the first semiconductor package, from a bottom half of the first semiconductor package; and
a second semiconductor package, including:
a leadframe including electrical leads,
one or more semiconductor die bonded and electrically coupled to the leadframe, and
mold compound for encapsulating the leadframe and one or more semiconductor die, the electrical leads emanating from sides of the second semiconductor package;
wherein the first semiconductor package is stacked atop the second semiconductor package, the leads emanating from the first semiconductor package aligning with and overlapping the leads of the second semiconductor package by a distance equal to or greater than 0.3 mm.

2. A portable memory package as recited in claim 1, wherein the first package is one of a TSOP, PSOP and a SSOP.

3. A portable memory package as recited in claim 1, wherein the second package is one of a TSOP, PSOP and a SSOP.

4. A portable memory package as recited in claim 1, wherein the first and second packages have one of thirty-two electrical leads, forty electrical leads, forty-eight electrical leads and fifty-six electrical leads.

5. A portable memory package as recited in claim 1, wherein the one or more semiconductor die in the first and second packages include one or more memory die and a controller chip.

6. A portable memory package as recited in claim 1, further comprising an adhesive layer for affixing the first and second packages to each other.

7. A portable memory package as recited in claim 1, wherein the electrical leads of the first package emanate from sides of the package at a bottom one-third of the package.

8. A portable memory package as recited in claim 1, wherein the electrical leads of the first package emanate from sides of the package at a bottom one-quarter of the package.

9. A portable memory package as recited in claim 1, wherein the electrical leads of the first package emanate from sides of the package approximately 0.15 mm from a bottom of the package.

10. A portable memory package as recited in claim 1, wherein the electrical leads of the second semiconductor package emanate from sides of the package approximately mid-way along a height of the package.

11. A portable memory package as recited in claim 1, wherein the electrical leads of the second semiconductor package are formed into a shape suitable to be surface mounted to a host device.

12. A portable memory package as recited in claim 1, wherein the electrical leads of the first and second semiconductor packages are welded together.

13. A portable memory package as recited in claim 12, wherein the electrical leads of the first and second semiconductor packages are ultrasonically welded together.

14. A portable memory package, comprising:
a first semiconductor package, including:
a leadframe including electrical leads,
one or more semiconductor die bonded and electrically coupled to the leadframe, the one or more semiconductor die including one or more memory die, and
mold compound for encapsulating the leadframe and one or more semiconductor die, the electrical leads emanating from sides of the first semiconductor package, between 0.1 mm and 0.3 mm from a bottom surface of the first package; and
a second semiconductor package, including:
a leadframe including electrical leads,
one or more semiconductor die bonded and electrically coupled to the leadframe, the one or more semiconductor die including one or more memory die, and
mold compound for encapsulating the leadframe and one or more semiconductor die, the electrical leads emanating from sides of the second semiconductor package;
wherein the first semiconductor package is stacked atop the second semiconductor package, leads emanating from the first semiconductor package overlapping and affixed to leads of the second semiconductor package.

15. A portable memory package as recited in claim 14, wherein the one or more semiconductor die in the first and second packages further include a controller chip.

16. A portable memory package as recited in claim 14, further comprising an adhesive layer for affixing the first and second packages to each other.

17. A portable memory package as recited in claim 14, wherein the electrical leads of the second semiconductor package emanate from sides of the package approximately mid-way along a height of the package.

18. A portable memory package as recited in claim 14, wherein the electrical leads of the second semiconductor package are formed into a shape suitable to be surface mounted to a host device.

19. A portable memory package as recited in claim 14, wherein the electrical leads of the first and second semiconductor packages are ultrasonically welded together.

20. A portable memory package, comprising:
a first semiconductor package, including:
a leadframe including electrical leads,
one or more semiconductor die bonded and electrically coupled to the leadframe, the one or more semiconductor die including one or more memory die, and
mold compound for encapsulating the leadframe and one or more semiconductor die, the electrical leads emanating from sides of the first semiconductor package, approximately 0.15 mm from a bottom surface of the first package;
a second semiconductor package, including:
a leadframe including electrical leads, the electrical leads bent to include a section capable of being surface mounted to a host device,
one or more semiconductor die bonded and electrically coupled to the leadframe, the one or more semiconductor die including one or more memory die, and
mold compound for encapsulating the leadframe and one or more semiconductor die, the electrical leads emanating from sides of the second semiconductor package; and
an adhesive layer affixing the first semiconductor package atop the second semiconductor package, the electrical leads of the first semiconductor package overhanging the leads of the second semiconductor package by a distance of approximately 0.3 mm and electrical leads of the first semiconductor package affixed to leads of the second semiconductor package.

21. A portable memory package as recited in claim 20, wherein the one or more semiconductor die in the first and second packages further include a controller chip.

22. A portable memory package as recited in claim 20, wherein the electrical leads of the second semiconductor package emanate from sides of the package approximately mid-way along a height of the package.

23. A portable memory package as recited in claim 20, wherein the electrical leads of the first and second semiconductor packages are ultrasonically welded together.
